(19) United States
(12) Patent Application Publication
(10) Pub. No.: US 2025/0330747 A1
(43) Pub. Date: Oct. 23, 2025

(54) MULTILEVEL SWITCHING DRIVER AND OPERATION

(71) Applicant: Cirrus Logic International Semiconductor Ltd., Edinburgh (GB)

(72) Inventors: Lingli ZHANG, Austin, TX (US); Yongjie CHENG, Austin, TX (US); Sakkarapani BALAGOPAL, Austin, TX (US); Andres BLANCO, Austin, TX (US); Christian LARSEN, Austin, TX (US); Abhishek MUKHERJEE, Austin, TX (US)

(73) Assignee: Cirrus Logic International Semiconductor Ltd., Edinburgh (GB)

(21) Appl. No.: 19/180,232

(22) Filed: Apr. 16, 2025

Related U.S. Application Data
(60) Provisional application No. 63/635,020, filed on Apr. 17, 2024.
(60) Provisional application No. 63/635,013, filed on Apr. 17, 2024.

(51) Int. Cl. H04R 3/00; H02M 3/155; H03K 3/017

(52) U.S. Cl. CPC H04R 3/00; H02M 3/155; H03K 3/017

(57) ABSTRACT

This application describes methods and apparatus for controlling a switching driver to drive a load with a differential drive signal, where the switching driver includes a DC-DC converter configured to generate a boosted voltage. A network of switches is configured so that first and second output nodes can be connected to any of first and second supply voltages or the boosted voltage. A controller controls the network of switches in at least first and second modes. In the first mode each of the first and second output nodes are modulated between the first and second supply voltages with a respective controlled duty cycle. In the second mode one of the first and second output nodes is modulated between the first supply voltage and the boosted voltage with a controlled duty-cycle and the other one of the first and second output nodes is maintained at the second supply voltage.

### BACKGROUND

The field of representative embodiments of this disclosure relates to methods, apparatus and/or implementations concerning or relating to switching drivers, e.g. to class-D amplifiers and the like, operable with three or more switching voltages.

Many electronic devices include transducer driver circuitry for driving a transducer with a suitable driving signal, for instance for driving an audio output transducer of the host device or a connected accessory, with an audio driving signal.

In some applications the driver circuitry may include a switching amplifier, e.g. a class-D amplifier or the like, for generating the drive signal. Switching amplifiers can be relatively power efficient and thus can be advantageously used in some applications. A switching amplifier generally operates to switch at least one output node between defined switching voltages, with a duty cycle that provides a desired average output voltage over the course of the duty cycle for the drive signal. Often, switching amplifiers may be configured to drive a load in a bridge-tied-load (BTL) configuration and thus the load may be connected between two output nodes, each of which may be modulated appropriately to generate the desired differential drive signal across the load.

In some switching amplifiers, each output node may be modulated between two defined switching voltages, say a positive supply voltage and ground. In some cases, however, there may be at least one additional voltage which can be used as a switching voltage and the switching amplifier may be operable to modulate each output node between selected ones of the switching voltages. For example, to provide an extended output range for a switching amplifier, a boosted voltage may be generated from the supply voltage by a suitable DC-DC converter. When a relatively high magnitude of output signal is required, the switching amplifier may operate to modulate the output nodes between the boosted voltage and ground. However, when a lower magnitude of output signal is required, the switching amplifier may operate to modulate the output nodes between the supply voltage and ground, as this can reduce the extent of the voltage modulation of the output nodes with benefits for EMI (electromagnetic interference).

Such a multilevel switching amplifier can operate well, however, there may be power losses associated with the generation of the boosted voltage by the DC-DC converter.

### SUMMARY

Embodiments of the present disclosure relate to switching drivers and to methods of operation that may provide advantages in terms of power efficiency.

According to an aspect of the disclosure there is provided a switching driver apparatus configured to drive a load connected between first and second output nodes with a drive signal based on an input signal. The switching driver apparatus comprises first and second supply nodes configured to receive first and second supply voltages respectively and a DC-DC converter configured to generate a boosted voltage. A network of switches is configured to selectively connect each of the first and second output nodes to any of the first supply voltage, the second supply voltage and the boosted voltage. A controller is configured to control the network of switches, the controller being operable to selectively control the network of switches in at least first and second modes. In the first mode each of the first and second output nodes are modulated between the first and second supply voltages with a respective controlled duty cycle. In the second mode one of the first and second output nodes is modulated between the first supply voltage and the boosted voltage with a controlled duty-cycle and the other one of the first and second output nodes is maintained at the second supply voltage.

In some examples, the first supply voltage is a positive supply voltage and the second voltage is ground. In some examples, the boosted voltage is a positive voltage of greater magnitude than the first supply voltage.

In some examples, the controller may be configured to operate in the first mode for a magnitude of the drive signal in a first range and to the operate in the second mode for a magnitude of the drive signal in a second, higher, range. The controller may be further operable to control the network of switches in a third mode in which each of the first and second output nodes are modulated between the boosted voltage and the second supply voltage with a respective controlled duty cycle. The controller may be configured to operate in the third mode for a magnitude of the drive signal in an intermediate range between the first and second ranges.

In some examples, the controller is configurable in a first regime to selectively operate in each of the first, second and third modes and is also configurable in a second regime to selectively operate in the first and third mode, without using the second mode.

In some examples, the controller may be configured to operate in the first mode with a first cycle frequency for modulation of the first and second output nodes and to operate in the second mode with a second, higher, cycle frequency for modulation of the relevant one of the first and second output nodes.

In some examples, the controller may be configured to determine which mode to operate in on a cycle-by-cycle basis. The controller may comprise a modulator configured to generate a modulator output signal for controlling switching of the network of switches based on input signal and the controller is configured to determine which mode to operate in based on said modulator output signal. The modulator may comprise a quantizer for generating the modulator output signal.

In some examples, the DC-DC converter may be an inductive boost converter. In some examples, the load may be an audio output transducer and where in the input signal is an audio input signal.

The switching driver apparatus may be implemented as an integrated circuit.

In another aspect, there is provided a switching driver apparatus configured to drive a load connected between first and second output nodes with a drive signal based on an input signal. The switching driver apparatus comprises first and second supply nodes configured to receive first and second supply voltages respectively and a DC-DC converter configured to generate a boosted voltage. A network of switches is configured to selectively connect each of the first and second output nodes to any of the first supply voltage, the second supply voltage and the boosted voltage. A controller is configured to control the network of switches, the controller being operable in a first mode in which one of the first and second output nodes is modulated between the first supply voltage and the boosted voltage with a controlled duty cycle and the other one of the first and second output nodes is maintained at the second supply voltage.

The controller may be further operable is a second mode in which each of the each of the first and second output nodes are modulated between the first and second supply voltages with a respective controlled duty cycle. The controller may be further operable is a third mode in which each of the each of the first and second output nodes are modulated between the boosted voltage and the second supply voltage with a respective controlled duty cycle. The controller may be configured to selectively operate in one of the first, the second or third modes on a cycle-by-cycle basis.

In a further aspect, there is provided a switching driver apparatus configured to drive a load with a drive signal based on an input signal, the switching driver apparatus comprising a DC-DC converter configured to receive a first supply voltage from a first voltage supply and generate a generated voltage; an output stage with at least a first output node for outputting the drive signal, and a controller configured to be operable in a first mode to control the output stage so as modulate the first output node between said generated voltage and said first supply voltage with a controlled duty-cycle, such that at least part of a load current is drawn from the first voltage supply via a path that does not include the DC-DC converter.

It should be noted that, unless expressly indicated to the contrary herein or otherwise clearly incompatible, then any feature described herein may be implemented in combination with any one or more other described features.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 illustrates one example of switching driver apparatus with a DC-DC converter;

FIG. 2 illustrates an example of a switching driver apparatus with a DC-DC converter in more detail;

FIGS. 3a and 3b illustrate example switching waveforms for operation in first and second mode;

FIG. 4 illustrates example switching waveforms for a switching driver apparatus operable in the first and second modes;

FIG. 5 illustrates example switching waveforms for operation in a third mode;

FIG. 6 illustrates example switching waveforms for a switching driver apparatus operable in the first, second and third modes; and

FIG. 7 illustrates one example of a suitable controller.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Embodiments of the disclosure relate to driver circuitry for driving a transducer and, in particular, to switching driver circuitry in which an output node can be switched between different switching voltages with a controlled duty cycle. Embodiments of the disclosure also relate to methods of operation of driver circuitry.

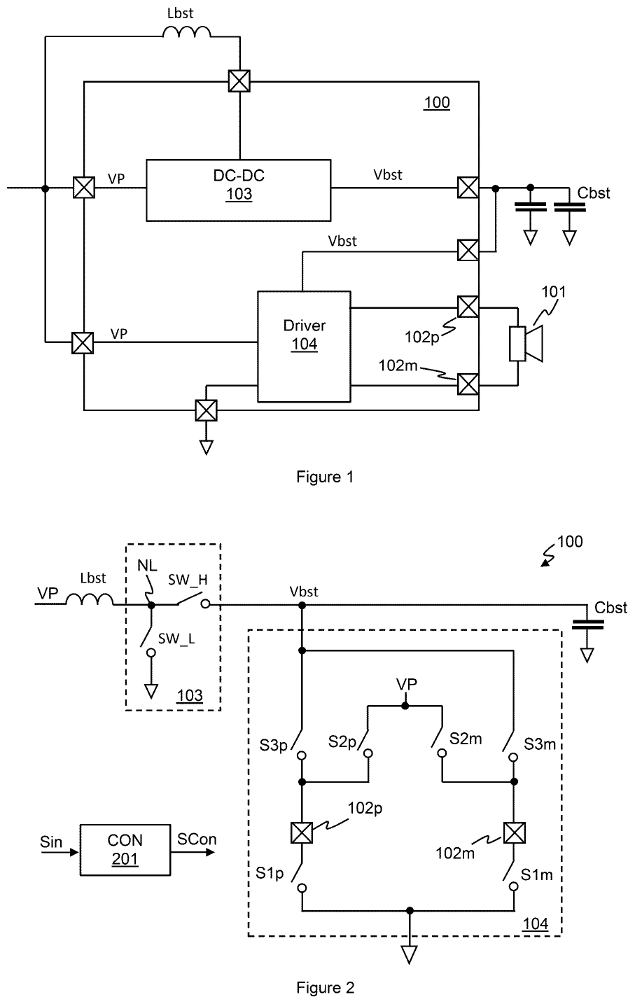

FIG. 1 illustrates one example of a driver apparatus 100 for driving a load 101 according to an embodiment. In this example the load 101 is illustrated as an audio output transducer, e.g. a loudspeaker, but it should be understood in other examples the driver apparatus may be implemented to drive other types of output transducer. The driver apparatus 100 is configured to drive the load 101 in a BTL configuration and thus the load 101 is connected between first and second output nodes 102p and 102m. In some embodiments there may be an output filter (not illustrated in FIG. 1), for instance an inductance-capacitance (LC) filter in the respective output path between each output node 102p and 102m and the load.

The driver apparatus 100 receives first and second supply voltages, which in this example are a positive supply voltage VP from a first supply and ground. The driver apparatus 100 also comprises a DC-DC converter 103 for generating an additional voltage, which in this example is boosted voltage Vbst, from the first and second supply voltages.

In some examples, the DC-DC converter 103 may be an inductive boost converter and may thus be operable with an inductor Lbst, as illustrated. In examples where the driver apparatus 100 is implemented as an integrated circuit, the inductor Lbst may be implemented as an external, i.e. off-chip component. FIG. 1 also illustrates that there may additionally be some capacitance Cbst to maintain the boosted voltage Vbst generated by the DC-DC converter 103, which may again be implemented, at least partly, by one or more external, i.e. off-chip, components. It should be understood, however, that other arrangements are possible and the DC-DC converter 103 could, for example, be implemented as a charge pump for providing a boosted output voltage.

The first and second supply voltages, VP and ground in this example, along with the boosted voltage Vbst, are provided to a driver 104 for use as switching voltages. As the driver 104 is operable to selective connect each of the output nodes 102p and 102m to any of these three switching voltages, the driver 104 may be referred to as Y-bridge driver (sometimes also known as a T-bridge driver), although it will be understood that this is simply a convenient label, and nothing is implied about the physical layout of the driver.

FIG. 2 illustrates one example implementation of the driver apparatus 100 in more detail.

The driver 104 comprises a switching output stage that, in this example, comprises switches S1p, S2p and S3p for connecting the first output node 102p to ground, the supply voltage VP or the boosted voltage Vbst respectively. Likewise, switches S1m, S2m and S3m selectively connect the second output node 102m to ground, the supply voltage VP or the boosted voltage Vbst respectively. The operation of the switches S1p, S2p, S3p, S1m, S2m and S3m are controlled by switch control signals Scon generated by controller 201 based on the input signal Sin, as will be described in more detail below. The controller 201 may comprise a modulator which may be implemented as an anlog modulator or as a digital modulator, or a hybrid modulator (part analog and part digital).

The DC-DC converter 103 is, in this example, a conventional inductive boost converter. An inductor node NL is, in use, connected to one end of the inductor Lbst with the other end of the inductor Lbst being connected to the supply voltage VP. Switch SW_L of the DC-DC converter 103 selectively connects the inductor node NL to a defined voltage, ground in this example, and switch SW_L of the DC-DC converter 103 selectively connects the inductor node NL to the output of the DC-DC converter 103. As will be understood by one skilled in the art, the DC-DC converter 103 will repeatedly operate in a switching cycle comprising a charging phase in which switch SW_L is closed (with SW_H open) to ramp up current in the inductor Lbst and an output phase in which switch SW_H is closed (with SW_L open) so as to output the boosted voltage Vbst, which is maintained by the capacitance Cbst. The switching of the switches SW_H and SW_L may also be controlled by the controller 201, as will be discussed below.

In some implementations, the controller 201 may be configured to control the driver 104 to selectively operate in either of at least two modes.

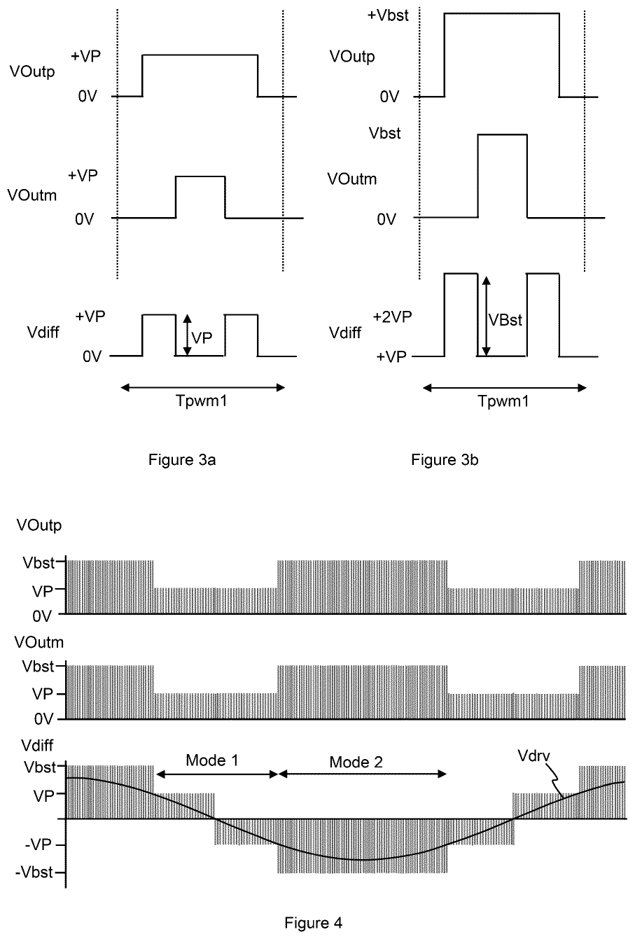

In a first mode each of the first and second output nodes 102p and 102m may be modulated between the supply voltage VP and ground with a controlled duty-cycle in each switching cycle. FIG. 3a illustrates example voltage waveforms for operation in the first mode, for a positive differential drive voltage (where, for the purposes of this application a positive differential drive voltage shall be taken to mean that the voltage at the first output node 102p is more positive than the voltage at the second output node 102m, on average over the course of the switching cycle). FIG. 3a thus illustrates the voltages Voutp and Voutm at the first and second output nodes 102p and 102m respectively over the course of the switching cycle period Tpwm1 and the resulting differential voltage Vdiff. The driver 104 may be switched at a first cycle frequency in the first mode, which defines the cycle period Tpwm1.

In this first mode, each of the first and second output nodes 102p and 102m is modulated between the supply voltage VP and ground, and for a positive differential drive voltage, the first output node 102p spends a greater proportion of the switching cycle at the supply voltage VP than the second output node 102m. This first mode of operation can be used to generate a differential drive voltage in the range of +VP to −VP.

In the first mode of operation, switches S3p and S3m are thus open (i.e. off and non-conducting) throughout the whole of the cycle period Tpwm1. Switches S2p and S1p are duty-cycled, i.e. toggled on and off in antiphase with one another, to provide the desired duty-cycle for the first output node 102p and switches S2p and S1p are likewise duty-cycled to provide the desired duty-cycle for the second output node 102p.

In the first mode of operation, the boosted voltage Vbst is not used and, in some embodiments, the DC-DC converter 103 may be operated in a relatively low-power burst mode of operation. That is, the DC-DC converter 103 may be occasionally operated in relatively short bursts so as maintain the voltage on the capacitance Cbst, e.g. to account for any leakage, so as to be ready for use when needed, but the DC-DC converter 103 may not be continually active, so as to reduce power consumption. During a burst of operation, which may occur at periodic intervals or based on some measure of the voltage on the capacitance Cbst, the switches SW_H and SW_L may be switched in antiphase at a DC-DC converter switching frequency, which generally will be significantly higher than the switching cycle frequency for the output stage.

In a second mode, each of the first and second output nodes 102p and 102m may be modulated between the boosted voltage Vbst and ground with a controlled duty-cycle in each switching cycle, at the same first cycle frequency. FIG. 3b illustrates example voltage waveforms for operation in the second mode, again for a positive differential drive voltage. FIG. 3b again illustrates the voltages Voutp and Voutm at the first and second output nodes 102p and 102m respectively over the course of the switching cycle period Tpwm1 and the resulting differential voltage Vdiff. In this second mode, each of the first and second output nodes 102p and 102m is modulated between the boosted voltage Vbst and ground, and for a positive differential drive voltage, the first output node 102p spends a greater proportion of the switching cycle at the boosted voltage Vbst than the second output node 102m. The second mode of operation can be used to generate a differential drive voltage in the range of +Vbst to −Vbst.

In the second mode of operation, the boosted voltage Vbst is used as a switching voltage and thus the DC-DC converter 103 is continually active and the switches SW_H and SW_L are switched in antiphase at the DC-DC converter switching frequency.

In some embodiments, the controller 201 may be configured to control the operation of the output stage to operate in the first mode or the second mode on a cycle-to-cycle basis. In some embodiments, the mode of operation may be determined based on comparing a signal indicative of the required output voltage with at least one threshold. In some implementations the output of a modulator of the controller, e.g. the output of a PWM (pulse width modulation) quantizer, may be used with the at least one threshold to determine the mode of operation. In this way, a cycle-to-cycle mode transition can be effectively instantaneous and cycle-to-cycle signal tracking can be achieved. Using the first mode of operation for a low-level signal can improve power efficiency, compared to continually operating in the second mode using the boosted voltage Vbst and can also be beneficial in reducing EMI.

FIG. 4 illustrates one example of switching waveforms showing how the driver apparatus 100 may swap between the first and second modes with signal level. FIG. 4 again shows the instantaneous voltages Voutm and Voutp, and the differential output voltage Vdiff and also illustrates the differential drive signal Vdrv, which corresponds to the average or filtered version of the instantaneous differential output Vdiff. It will be understood that on the time scale of the evolution of the output drive signal Vdrv, the individual switching cycles of modulation can't be accurately represented and thus FIG. 4 is just representative of the relevant modulation applied. It can be seen from FIG. 4 that for a low-level signal, within the range of about +VP to −VP or less, the driver 104 is operated in the first mode, whereas for higher signal levels, the driver 104 is operated in the second mode.

Whilst such operation can provide advantages as described, operation in the second mode does result in the load current essentially being drawn via the DC-DC converter 103, i.e. energy transfer from the first supply to the load is via the DC-DC converter 103, which may involve some inefficiency.

In some embodiments, the controller 201 may be configured to be control the driver 104 to operable in a third mode of operation. In the third mode of operation, the driver 104 may be controlled to drive the load in a single-ended manner by modulating one of the output nodes between the boosted voltage Vbst and the supply voltage VP, whilst the other output node is held at ground throughout the switching cycle. In this third mode of operation, the cycle frequency may be varied to a second cycle frequency, which may be substantially double the first cycle frequency, so that any tones in the differential voltages remain at the same frequency (output of the signal band of interest).

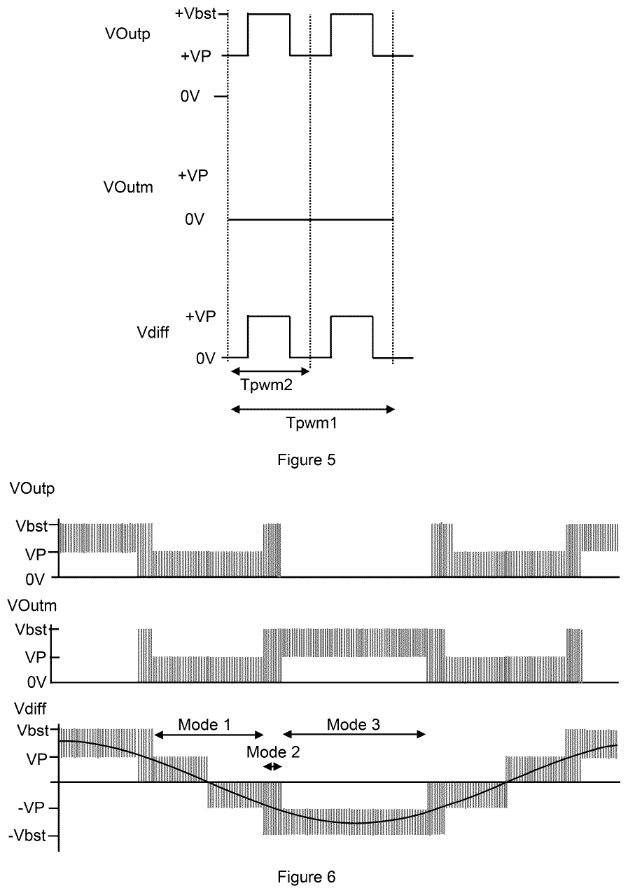

FIG. 5 illustrates example voltage waveforms for operation in the third mode, again for a positive differential drive voltage. FIG. 5 again illustrates the voltages Voutp and Voutm at the first and second output nodes 102p and 102m respectively over the course of the switching cycle period Tpwm2 (at the second cycle frequency) and the resulting differential voltage Vdiff. In this third mode, for a positive differential drive signal Vdrv, the first output node 102p is modulated between the boosted voltage Vbst and the supply voltage VP, whilst the second output node 102m is connected to ground throughout the switching cycle. For a negative differential drive signal Vdrv, it would instead be the second output node 102m that is modulated between the boosted voltage Vbst and the supply voltage VP, whilst the first output node 102p is connected to ground.

In the third mode of operation, for a positive differential drive voltage, switch S1m will be closed (with switches S2m and S3m open) throughout the switching cycle. Switch S1p will be open throughout the switching cycle and switches S3p and S2p will be duty-cycled, i.e. together on and off in antiphase with a controlled duty-cycle at the switching cycle frequency.

In this third mode of operation, the boosted voltage Vbst is used as a switching voltage and thus the DC-DC converter 103 is continually active and the switches SW_H and SW_L are switched in antiphase at the DC-DC converter switching frequency.

Operating in this third mode of operation can have advantages in terms of power efficiency, as some of the output power in this mode is drawn directly from the first supply (i.e. the source of the supply voltage VP), i.e. not via the DC-DC converter 103. As noted above, in the second mode of operation, all of the output power is effectively drawn indirectly from the first supply via the DC-DC converter 103. The DC-DC converter 103 will not be 100% efficiency and thus providing power via the DC-DC converter 103 will inevitably involve some losses. Drawing power directly from the first supply as far as possible can reduce the losses associated with operation of the DC-DC converter 103 and improve efficiency.

During the part of the switching cycle where the output node 102p (or 102m) is modulated to the boosted voltage Vbst, switch S3p (or S3m as appropriate) will be closed which provides a first current path from the first supply voltage to the load and then ground, via the DC-DC converter 103. During the part of the switching cycle where the output node 102p (or 102m) is modulated to the supply voltage VP, switch S2p (or S2m as appropriate) will be closed which provides a second current path from the first supply directly to the load and then to ground. At least part of the load current will be delivered directly to the load from the first supply, thus avoiding the losses associated with the DC-DC converter 103. As such a given output power may be provided more efficiently when operating in the third mode than the second mode.

Operation in the third mode can be used to generate a positive or negative differential drive voltage with a magnitude in the range of Vbst to VP.

As discussed above, the controller 201 may be configured to control the operation of the output stage of the driver 104 to operate in the first mode or the third mode on a cycle-to-cycle basis and the mode of operation may be determined based on comparing a signal indicative of the required output voltage with at least one threshold, e.g. by using the output of a quantizer of a modulator of the controller.

In some embodiments, the controller 201 could be configured to swap directly between the first and third modes. It will be understood, however, that the maximum differential drive voltage that can be generated when operating in the first mode will have a magnitude equal to the supply voltage VP, and this requires one output node to be driven to the supply voltage VP for the whole of the switching cycle (i.e. a duty-cycle of 100%) whilst the other output node is driven to ground for the whole of the switching cycle. The minimum differential drive voltage that can be generated when operating in the third mode will also have a magnitude VP, and this again require the relevant output node to be driven to the supply voltage VP for the whole of the switching cycle (but this corresponds to a duty-cycle of 0% in terms of the proportion of time spent at the highest switching voltage in the relevant mode). In at least some modulator designs it may be difficult to achieve very high levels of duty-cycle, i.e. duty-cycles around 100%, and/or swapping between a duty-cycle of 100% and 0% may lead to some distortion in the output signal.

To avoid these issues, in some embodiments the controller 201 may be configured to transition between the first and third modes by using the second mode.

FIG. 6 illustrates one example of switching waveforms showing how the driver apparatus 100 may swap between the first, second and third modes with signal level. FIG. 6 again shows a representations of the instantaneous voltages Voutm and Voutp, and the differential output voltage Vdiff and also illustrates the differential drive signal Vdrv, which corresponds to the average or filtered version of the instantaneous differential output Vdiff. It can be seen from FIG. 4 that for a low-level signal, below a first threshold of magnitude (which is lower than the magnitude of the supply voltage VP), the driver 104 is operated in the first mode. Between this first threshold of magnitude and a second, higher, threshold of magnitude (which is greater than the magnitude of the supply voltage VP), the driver 104 is operated in the second mode. For an output magnitude above the second threshold, the driver 104 is operated in the third mode for power efficiency. The first threshold may correspond to a desired upper limit of duty-cycle when operating in the first mode and the second threshold may correspond to a desired upper limit of duty-cycle when operating in the first mode.

Using the third mode for signals in a high signal level range, above the second threshold of magnitude, thus can provide power efficiency compared to the operation described with reference to FIG. 4, which only uses the second mode for signals in this magnitude range.

However, the operation to draw some load current directly from the first supply, rather than all the load current via the DC-DC converter 103 does mean that the current delivered via the DC-DC converter 103 no longer represents the total current draw from the first supply voltage in operation of the driver 104.

In some implementations, as will be understood by one skilled in the art, some current limiting may be applied in the DC-DC converter 103 so as to limit the current draw from the first supply (i.e. the source of the supply voltage VP). There may be some maximum current limiting to avoid drawing a current at a level which is high enough that could cause damage to components of the driver apparatus, but also there may typically be some average current limiting to limit the average current drawn from the first supply. For example, for portable devices which are operable such that the first supply may, at times, be a battery, there may be a desire to limit the average current that can be drawn, in use, from the battery.

Conventionally, the average current limiting may be applied within the DC-DC converter 103, based on a defined current limit. One skilled in the art would be well aware of various ways in which an average current limit could be implemented in a DC-DC converter 103 such as an inductive boost converter.

An issue can arise in operation in the third mode if the defined current limit applied in the DC-DC converter 103 is set to be equal to the maximum desired average current draw from the first supply, in that the DC-DC converter 103 may be operating to draw a current equal to the defined current limit but some additional current will be drawn from directly from the first supply for part of the switching cycle, and the maximum desired average current draw may thus be exceed.

Purely by way of example, consider that the driver 104 is operating in the third mode of operation and the average load current is 1 A. The proportion of this average load current that is delivered via the DC-DC converter 103 will have a dependence on the duty-cycle of operation (of the relevant output node that is being modulated between Vbst and VP). For example, if the duty-cycle were at 70%, in terms of proportion of the switching cycle spent at the boosted voltage Vbst, then the average load current drawn from the DC-DC converter 103 may be 0.7 A, with 0.3 A being drawn on average directly from the first supply. If the defined current limit for the DC-DC converter were set at the level of a desired maximum average current draw from the first supply, say 2 A for example, then it could be the case that the operation of the DC-DC converter 103 would result in an average current draw of 2 A from the first supply. In this case, the additional average current draw of 0.3 A directly from the first supply would result in a total average current draw of 2.3 A, which exceeds the desired maximum average current draw in this example.

It would be possible to set a static defined current limit for the DC-DC converter 103 based on an expected maximum of average current draw direct from the first supply when operating in the third mode, but such a static limit would thus be too low for other operating conditions (when the draw direct from the first supply is less than the maximum) and thus could result in unnecessary current limiting with a negative impact on performance.

In at least some embodiments the defined current limit (of maximum average current draw) for the DC-DC converter 103 may be dynamically varied in use, when operating in the third mode of operation. The defined current limit may be set based on an indication of the current drawn directly from the first supply when operating in the third mode. The indication of the current drawn directly from the first supply when operating in the third mode may, in some cases, be based on an indication of the load current and on the present duty-cycle of operation in the third mode.

In many switching driver implementations, the output current may be monitored for other reasons and thus an indication of the load current may already be available. The duty-cycle of operation is determined by the controller 201 and thus is known.

Thus, for the example discussed above, where the average load current is 1 A and the duty-cycle is 70%, so the average current draw directly from the first supply is 0.3 A, the defined current limit for the DC-DC converter 103 may be set at 1.7 A, so that maximum average current drawn by the DC-DC converter 103 together with the average current draw directly from the first supply do not exceed the desired maximum average current draw of 2 A in this example.

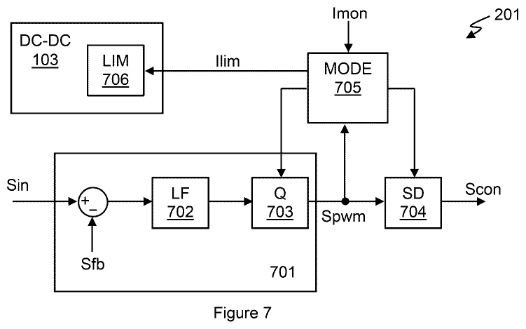

FIG. 7 illustrates one example of a possible arrangement of a controller 201 according to an embodiment. FIG. 7 illustrates that the input signal Sin may be supplied to a modulator 701 which generates a PWM control signal Spwm for controlling switching of the output stage of the driver 104. One skilled in the art will be aware of various different modulator designs that could be implemented, but the example of FIG. 7 illustrates that the input signal may be combined with a feedback signal Sfb and filtered by a loop filter 702 and supplied to quantizer 703 to generate the PWM signal Spwm. The PWM signal be supplied to a switch driver 704 to generate the switch control signals Scon. The PWM signal Spwm output from the modulator may also be input to a mode controller 705 which determines the relevant mode of operation, which may involve controlling which switches are switched in response to the PWM signal Spwm and using appropriate carriers for the quantizer 703.

In the example of FIG. 7, the mode controller 705 may also receive an indication IMON of the output current and, when operating in the third mode, may set a dynamic current limit llim of average current for DC-DC converter 103, e.g. to be applied by a limiter 706 of the DC-DC converter 103.

Being able to operate in the third mode and to dynamically control the average current limit applied by the DC-DC converter 103 thus can provide the power efficiency benefits of operation in the third mode with the ability to ensure that the average current draw stays below a desired maximum. In some use cases, however, it may be preferable for all current limiting to be applied via the DC-DC converter 103, in which case it may be desirable for the switching driver apparatus to operate in the first and second modes only, as discussed with reference to FIG. 4. In some embodiments the switching driver may be configurable to operate in a two-level mode (swapping between the first and second modes) or a three-level mode (swapping between the first, second and third modes).

Note the examples above have been described in the context of switching driver operable with three switching voltages, but some of the principles could be extended to operation with a greater number of switching voltages. For instance, the DC-DC converter could be operable in different modes to provide different output voltages and/or there may be more than one DC-DC converter for providing different boosted voltages. In general, however, switching between the output voltage provided by a DC-DC converter and the supply voltage in a single ended modulation scheme may allow at least some energy transfer directly from the voltage supply, rather than the DC-DC converter with some advantages in efficiency. The discussion has also focussed on the supply voltages being a positive supply voltage and ground, but at least one of the supply voltages could be a negative supply voltage and/or the DC-DC could generate a negative voltage.

The driver apparatus of embodiments of the disclosure may be suitable for driving an output transducer. The output transducer may be, in some implementations, be an audio output transducer such as a loudspeaker or the like. The output transducer may be a haptic output transducer. In some implementation the output transducer may be driven in series with an inductor, i.e. there may be an inductor in an output path between an output node of the switching driver and the load. In some implementations the transducer may be a piezoelectric or ceramic transducer.

Embodiments may be implemented as an integrated circuit. Embodiments may be implemented in a host device, especially a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. It will be understood that embodiments may be implemented as part of a system provided in a home appliance or in a vehicle or interactive display. There is further provided a host device incorporating the above-described embodiments.

The skilled person will recognise that some aspects of the above-described apparatus and methods, for instance aspects of controlling the switching control signals to implement the different modes, may be embodied as processor control code, for example on a non-volatile carrier medium such as a disk, CD- or DVD-ROM, programmed memory such as read only memory (Firmware), or on a data carrier such as an optical or electrical signal carrier. For some applications, embodiments may be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A switching driver apparatus configured to drive a load connected between first and second output nodes with a drive signal based on an input signal, the switching driver apparatus comprising:
first and second supply nodes configured to receive first and second supply voltages respectively;
a DC-DC converter configured to generate a boosted voltage;
a network of switches configured to selectively connect each of the first and second output nodes to any of the first supply voltage, the second supply voltage and the boosted voltage; and
a controller configured to control the network of switches, the controller being operable to selectively control the network of switches in at least first and second modes,
wherein in the first mode each of the first and second output nodes are modulated between the first and second supply voltages with a respective controlled duty cycle; and
in the second mode one of the first and second output nodes is modulated between the first supply voltage and the boosted voltage with a controlled duty-cycle and the other one of the first and second output nodes is maintained at the second supply voltage.

2. The switching driver apparatus of claim 1 wherein the first supply voltage is a positive supply voltage and the second voltage is ground.

3. The switching driver apparatus of claim 2 wherein the boosted voltage is a positive voltage of greater magnitude than the first supply voltage.

4. The switching driver apparatus of claim 1 wherein the controller is configured to operate in the first mode for a magnitude of the drive signal in a first range and to the operate in the second mode for a magnitude of the drive signal in a second, higher, range.

5. The switching driver apparatus of claim 4 wherein the controller is further operable to control the network of switches in a third mode in which each of the first and second output nodes are modulated between the boosted voltage and the second supply voltage with a respective controlled duty cycle.

6. The switching driver apparatus of claim 5 wherein the controller is configured to operate in the third mode for a magnitude of the drive signal in an intermediate range between the first and second ranges.

7. The switching driver apparatus of claim 5 wherein the controller is configurable in a first regime to selectively operate in each of the first, second and third modes and is also configurable in a second regime to selectively operate in the first and third mode, without using the second mode.

8. The switching driver apparatus of claim 1 wherein the controller is configured to operate in the first mode with a first cycle frequency for modulation of the first and second output nodes and to operate in the second mode with a second, higher, cycle frequency for modulation of the relevant one of the first and second output nodes.

9. The switching driver apparatus of claim 1 wherein the controller is configured to determine which mode to operate in on a cycle-by-cycle basis.

10. The switching driver apparatus of claim 9 wherein the controller comprises a modulator configured to generate a modulator output signal for controlling switching of the network of switches based on input signal and the controller is configured to determine which mode to operate in based on said modulator output signal.

11. The switching driver apparatus of claim 10 wherein the modulator comprises a quantizer for generating the modulator output signal.

12. The switching driver apparatus of claim 1 wherein the DC-DC converter is an inductive boost converter.

13. The switching driver apparatus of claim 1 wherein the load is an audio output transducer and where in the input signal is an audio input signal.

14. The switching driver apparatus of claim 1 implemented as an integrated circuit.

15. A switching driver apparatus configured to drive a load connected between first and second output nodes with a drive signal based on an input signal, the switching driver apparatus comprising:
first and second supply nodes configured to receive first and second supply voltages respectively;
a DC-DC converter configured to generate a boosted voltage;
a network of switches configured to selectively connect each of the first and second output nodes to any of the first supply voltage, the second supply voltage and the boosted voltage; and
a controller configured to control the network of switches, the controller being operable in a first mode in which one of the first and second output nodes is modulated between the first supply voltage and the boosted voltage with a controlled duty cycle and the other one of the first and second output nodes is maintained at the second supply voltage.

16. The switching driver apparatus of claim 15 wherein the controller is further operable is a second mode in which each of the each of the first and second output nodes are modulated between the first and second supply voltages with a respective controlled duty cycle.

17. The switching driver apparatus of claim 16 wherein the controller is further operable is a third mode in which each of the each of the first and second output nodes are modulated between the boosted voltage and the second supply voltage with a respective controlled duty cycle.

18. The switching driver apparatus of claim 17 wherein the controller is configured to selectively operate in one of the first, the second or third modes on a cycle-by-cycle basis.

19. A switching driver apparatus configured to drive a load with a drive signal based on an input signal, the switching driver apparatus comprising:
a DC-DC converter configured to receive a first supply voltage from a first voltage supply and generate a generated voltage;
an output stage with at least a first output node for outputting the drive signal,
a controller configured to be operable in a first mode to control the output stage so as modulate the first output node between said generated voltage and said first supply voltage with a controlled duty-cycle, such that at least part of a load current is drawn from the first voltage supply via a path that does not include the DC-DC converter.
